(19) United States
(12) Patent Application Publication
(10) Pub. No.: US 2009/0111263 A1
(43) Pub. Date: Apr. 30, 2009

(54) Method of Forming Programmable Via Devices

(76) Inventors: Kuan-Neng Chen, White Plains, NY (US); Sampath Purushothaman, Yorktown Heights, NY (US)

Correspondence Address: RYAN, MASON & LEWIS, LLP, 90 FOREST AVENUE, LOCUST VALLEY, NY, 11560, US

(21) Appl. No.: 11/924,636

(22) Filed: Oct. 26, 2007

(51) Int. Cl. H01L 21/44

(52) U.S. Cl. 438/667; 257/E21.597

(57) ABSTRACT

A device is formed by providing a contact via in a dielectric layer, providing a capping layer overlying at least a portion of the contact via, and forming a conductive element in physical contact with the capping layer. The conductive element is formed using a masked deposition process. This process comprises forming a seed layer overlying the capping layer and at least a portion of an uppermost surface of the dielectric layer, forming a masking layer on the seed layer, the masking layer defining an opening exposing a portion of the seed layer that overlies the capping layer, and selectively depositing a conductive material onto the exposed portion of the seed layer.

### FIELD OF THE INVENTION

The present invention is directed generally to integrated circuits, and, more particularly, to programmable via devices in integrated circuits.

### BACKGROUND OF THE INVENTION

Reconfigurable circuits have been widely used in the semiconductor industry for field programmable gate arrays (FPGAs) and for the repair of defective memory elements. Moreover, reconfigurable circuits such as FPGAs are also anticipated to play a significant role in the new Three Dimensional Integration (3DI) technology currently under development. 3DI structures typically include multilayer structures that can form a single chip combination with different functionalities. In these multilayer (and multifunctional) systems, reconfigurable circuit connections are needed to provide controllable logic functionality, memory repair, data encryption, as well as other functions.

A programmable via device (PVD) is an enabling technology for high-performance reconfigurable logic applications such as those required for 3DI applications. As the name would suggest, a PVD comprises contact vias (i.e., vertical contacts) whose resistance can be temporarily or permanently switched (i.e., programmed) between two or more resistance states by applying one or more signals to the device. Recently, the possibility of using phase change materials (PCMs) in PVDs has gained momentum as more is learned about these materials and their integration into integrated circuits. Currently, a ternary alloy of germanium (Ge), antimony (Sb), and tellurium (Te) (GST) (e.g., Ge₂Sb₂T₅) is showing the greatest promise for use in practical PCM-based PVDs, although several other materials are presently under investigation. At room temperature and at moderately elevated temperatures, GST is stable in two phases, a crystalline phase, which is a moderately good conductor of electrical current, and an amorphous phase, which is largely insulating. The GST in a PVD may be converted between these phases by applying a pulse of current (“switching current pulse”) to a heating feature that is located proximate to the GST. This switching current pulse, in turn, acts to resistively heat the heating feature and, as a result, the adjacent GST. A RESET switching current pulse is designed to rapidly heat the GST above its melting point and then to rapidly quench the melted material so that its disordered arrangement of atoms is retained. In this manner, the RESET switching current pulse converts at least a fraction of the GST from a crystalline phase to an amorphous phase. In contrast, a SET switching current pulse is designed to anneal the GST at temperatures below its melting point for a time somewhat longer than the RESET pulse. Such a SET switching pulse converts at least a fraction of the GST from the amorphous phase into the crystalline phase.

With the strong likelihood of their use in future technologies, there remains a need for refined fabrication techniques for PCM-based PVDs. Ideally such fabrication techniques will be compatible with conventional complimentary-metal-oxide-semiconductor (CMOS) processing.

### SUMMARY OF THE INVENTION

Embodiments of the present invention address the above-identified need by providing methods of fabricating PCM-based PVDS that are compatible with conventional CMOS processing.

In accordance with an aspect of the invention, a device is formed by providing a contact via in a dielectric layer, providing a capping layer overlying at least a portion of the contact via, and forming a conductive element in physical contact with the capping layer. The conductive element is formed using a masked deposition process. This process comprises forming a seed layer overlying the capping layer and at least a portion of an uppermost surface of the dielectric layer, forming a masking layer on the seed layer, the masking layer defining an opening exposing a portion of the seed layer that overlies the capping layer, and selectively depositing a conductive material onto the exposed portion of the seed layer.

In accordance with one of the above-identified embodiments of the invention, a PVD is fabricated by forming a contact via on a heater in a dielectric layer. The contact via comprises a PCM and is operative to change between lower and higher electrical resistance states in response to an application of an electrical signal to the heater. A capping layer is formed over the contact via and a conductive element is formed over the capping layer. The capping layer acts as a diffusion barrier between the contact via and the conductive element. The conductive element is formed by a masked deposition process. In this process, a seed layer is deposited on the capping layer and on the dielectric layer and then patterned to define an opening that exposes a portion of the seed layer overlying the capping layer. A selective deposition process is then utilized to deposit a conductive material on the exposed portion of seed layer. Later, the masking layer and any portion of the seed layer that is not covered by the conductive material are removed.

Advantageously, the above-described method embodiment further allows conductive elements that contact the heater to be formed using the same masked deposition process used to form the conductive element that contacts the capping layer. Moreover, the method tends to form contacts to the heater and capping layer with lower contact resistances than other methods.

These and other features and advantages of the present invention will become apparent from the following detailed description which is to be read in conjunction with the accompanying drawings.

### BRIEF DESCRIPTION OF THE DRAWINGS

FIG. 1 shows a sectional view of a PVD that may be formed using a method in accordance with an illustrative embodiment of the invention.

FIG. 2 shows a flow chart of an illustrative method in accordance with an illustrative embodiment of the invention for forming the FIG. 1 PVD.

FIGS. 3A-3M show sectional views of the FIG. 1 PVD in various stages of formation using the FIG. 2 method.

### DETAILED DESCRIPTION OF THE INVENTION

This invention will be illustrated herein in conjunction with an exemplary PVD for use in integrated circuits and methods for forming such a PVD. Such a device may be used in a range of applications including, but not limited to, reconfigurable circuits. It should be understood, however, that the invention is not limited to the particular materials, features, and processing steps shown and described herein. Modifications to the illustrative embodiments will be apparent to those skilled in the art.

Particularly with respect to processing steps, it is emphasized that the descriptions provided herein are not intended to encompass all of the processing steps that may be required to successfully form a functional device in an integrated circuit. Rather, certain processing steps which are conventionally used in forming integrated circuit devices, such as, for example, wet cleaning and annealing steps, are purposefully not described herein for economy of description. However one skilled in the art will readily recognize those processing steps omitted from this generalized description. Moreover, details of conventional semiconductor processing steps described herein will only be described generally since the details of these conventional processes will be known to one skilled in the art and since there are commercially available semiconductor processing tools for implementing these processing steps. Details of the processing steps used to fabricate semiconductor devices may be found in a number of publications, for example, S. Wolf and R. N. Tauber, Silicon Processing for the VLSI Era, Volume 1, Lattice Press, 1986; and S. Wolf, Silicon Processing for the VLSI Era, Volume 4: Deep Submicron Process Technology, Lattice Press, 2002, both of which are incorporated herein by reference.

The term “phase change material” (PCM) as used herein is intended to encompass any material displaying more than one programmable electrical resistance state capable of use in integrated circuits. PCMs comprise, for example, various chalcogenides and transition metal oxides and include, but are not limited to, doped or undoped Ge₂Sb₂Te₅, GeSb, GeSb₄, SbTe, SrTiO₃, BaTiO₃, (Sr,Ba)TiO₃, SrZrO₃, Ca₂Nb₂O₇, (Pr,Ca)MnO₃, Ta₂O₅, NiOₓ and TiOₓ, as well as other suitable materials.

It should also be understood that the various layers and/or regions shown in the accompanying figures are not drawn to scale, and that one or more layers and/or regions of a type commonly used in integrated circuits may not be explicitly shown in a given figure. This does not imply that the layers and/or regions not explicitly shown are omitted from the actual integrated circuit.

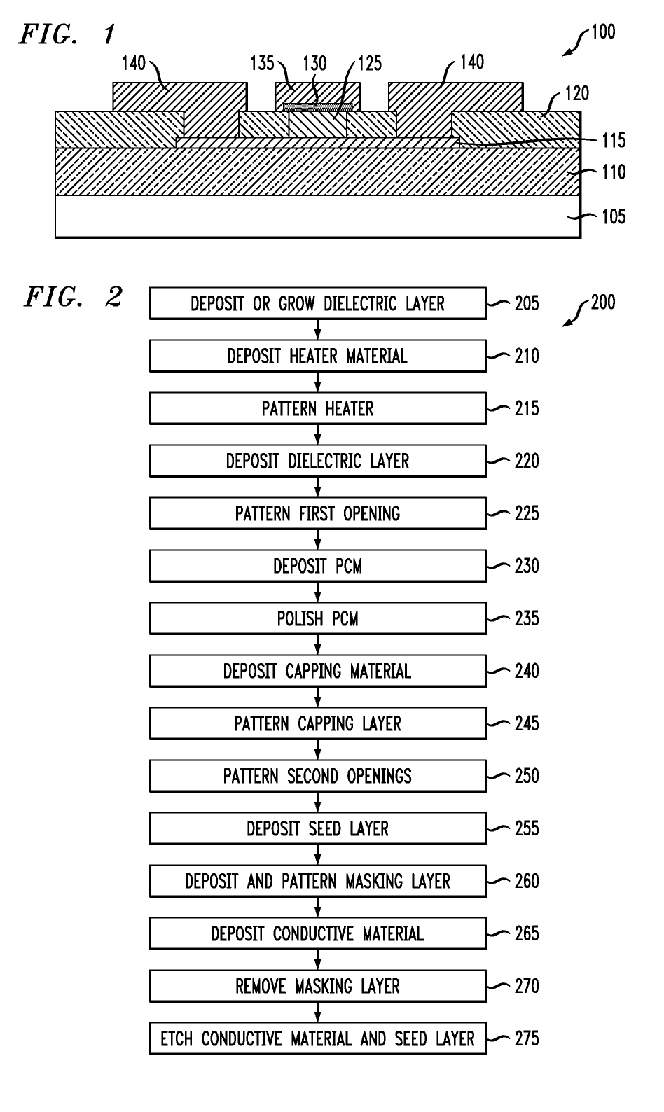

FIG. 1 shows a PVD 100 that may be formed using a method in accordance with an illustrative embodiment of the invention. This illustrative PVD comprises a substrate 105, a lower dielectric layer 110, a heater 115, and an upper dielectric layer 120. A contact via 125 spans vertically between the heater and a capping layer 130 that is disposed on top of the contact via. A first conductive element 135 physically contacts the capping layer, and two second conductive elements 140 extend through the dielectric layer and physically contact the heater.

In the illustrative PVD 100, the substrate preferably comprises silicon or some other suitable semiconductor material, while the lower dielectric layer 110 and upper dielectric layer 120 preferably comprise silicon oxide (e.g., SiOₓ) or some other suitable dielectric material such as silicon nitride (e.g., SiₓN_{y}), silicon carbonitride (e.g., SiCₓN_{y}), silicon-carbon hydroxide (e.g., SiCOH), or silicon oxynitride (e.g., SiOₓN_{y}). Moreover, the heater 115 preferably comprises tantalum silicon nitride (e.g., TaₓSi_{y}N_{z}) or some other suitable conductive material with a relatively high resistivity (e.g., from about 100 ohm-cm to about 1,000 ohm-cm) such as, but not limited to, tantalum nitride (e.g., TaN), chromium oxide (e.g., CrOₓ), or ruthenium oxide (e.g., RuOₓ). The contact via 125 preferably comprises GST or some other suitable PCM (further described above), while the first and second conductive elements 135, 140 preferably comprise a conductive material such as tungsten, copper, aluminum, or alloys thereof. Each of the conductive elements may also include a thin adhesion layer where it contacts other structures. These adhesion layers may, for example, comprise titanium nitride (e.g, TiN) on a thin layer of titanium, or tantalum nitride (e.g., TaN) on a thin layer of tantalum.

The material for the capping layer 130 is preferably chosen so that the capping layer acts as diffusion barrier between the contact via 125 and the first conductive element 135. The capping layer may, for example, comprise a layer of titanium nitride (e.g., TiN) deposited on a thin layer (e.g., less than about one nanometer) of titanium, or a layer of tantalum nitride (e.g., TaN) deposited on a thin layer oftantalum. The purely metallic sublayers typically act as adhesion layers for the metal nitride sublayers. The metal nitride sublayers typically act as the diffusion barriers.

In all cases, however, it should be noted that the above-described choices of materials for the elements in the PVD 100 are merely illustrative and that other suitable materials may be utilized as substitutes for the ones explicitly presented herein. Embodiments comprising such alternative materials will be apparent to one skilled in the art and may still fall within the scope of the invention.

The PVD 100 is programmable between two resistance states by applying a switching current pulse between the two second conductive elements 140. Such a signal application causes the switching current pulse to pass through the heater 115 where it is partially converted into heat by resistive (i.e., ohmic) heating. This, in turn, causes the adjacent contact via 125 to be heated by conduction. A RESET switching current pulse is applied to the PVD in order to rapidly melt and quench the contact via and to thereby convert at least a fraction of the PCM from its moderately conductive crystalline phase to its insulating amorphous phase. A RESET pulse may, as an example, ramp up to peak current in about ten nanoseconds (ns), stay at peak current for 50 ns, and ramp down in two ns. A SET switching current pulse is, in contrast, applied to the PVD in order to anneal the contact via below its melting point and to convert at least a fraction of the PCM from its amorphous phase into its crystalline phase. A SET switching pulse may, for example, ramp up to peak current in about ten ns, stay at peak current for about 1,000 ns, and ramp down in about 200 ns. In this manner, the PVD may be cycled between resistance states.

After being so programmed, any signals applied to the PVD 100 that must travel through the contact via 125 will be affected by the PVD's programmed state. For example a signal transmitted between the first conductive element 135 and either second conductive element 140 will be affected. The resistance of a PVD after a suitable SET switching current pulse may be more than three orders of magnitude higher than the resistance after a suitable RESET switching current pulse.

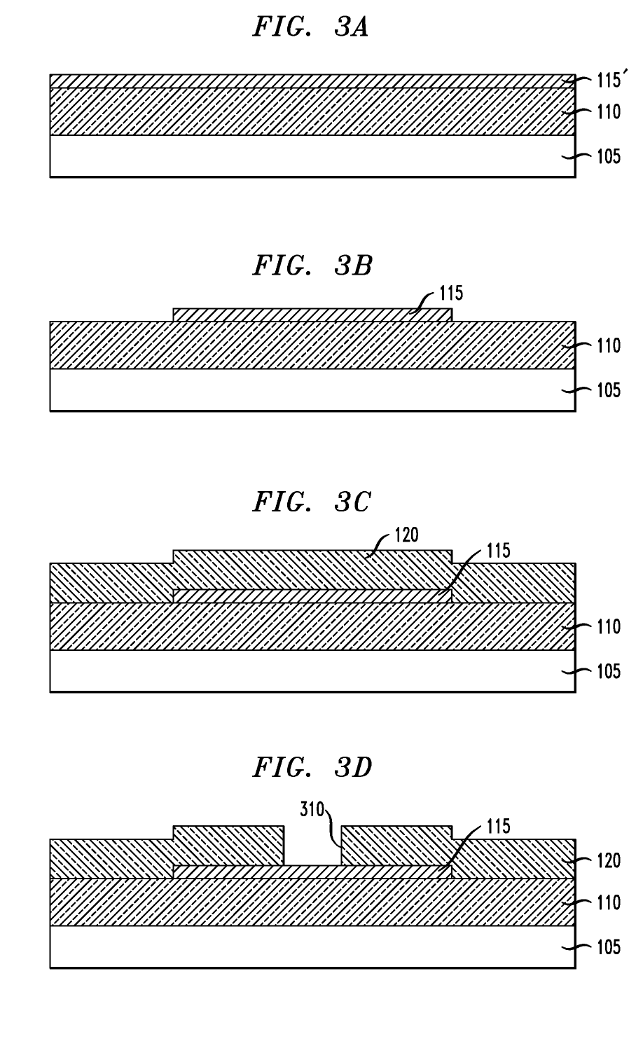

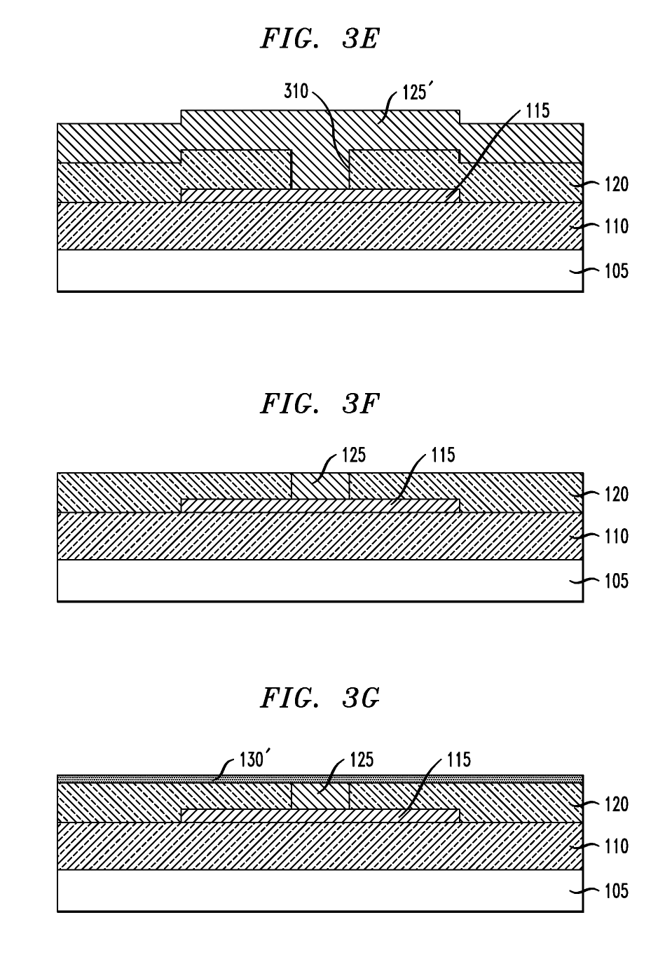

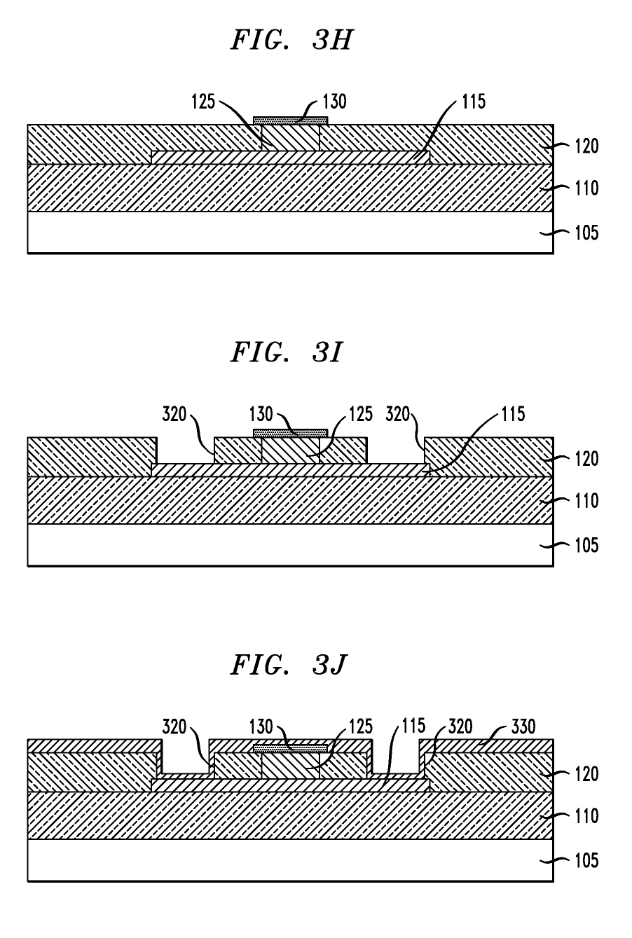

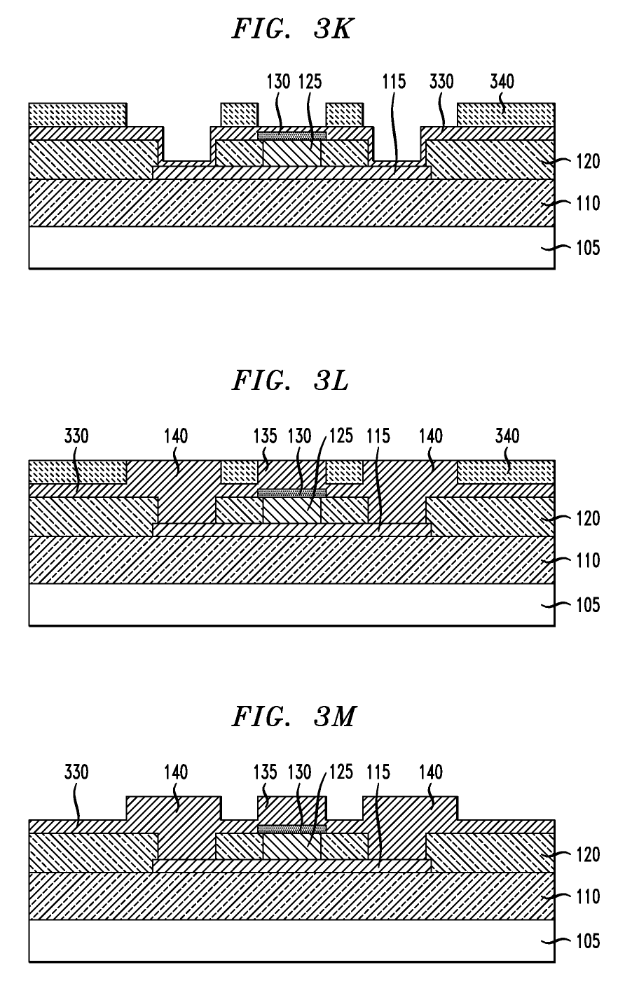

FIG. 2 shows a flow chart of an illustrative method 200 in accordance with aspects of the invention for forming the PVD 100. Moreover, FIGS. 3A-3M show sectional views of the PVD in various stages of formation using this illustrative method.

In step 205 of the method 200, a dielectric layer is grown or deposited on the substrate 105 to form the lower dielectric layer 110. If the lower dielectric layer comprises silicon oxide, for example, it may be thermally grown on a silicon substrate. Next, in step 210, a layer of heater material 115′ for the heater 115 is deposited on the lower dielectric layer, as shown in FIG. 3A. In step 215, the layer of heater material is patterned such that it forms the discrete heater, as shown in FIG. 3B.

In step 220, a layer of dielectric material is deposited on the film stack to form the upper dielectric layer 120, as shown in FIG. 3C. Subsequently, in step 225, a first opening 310 is patterned into the upper dielectric layer. The first opening lands on the heater 115, as shown in FIG. 3D.

In step 230, a layer of PCM 125′ for the contact via 125 is conformally deposited onto the uppermost surface of the upper dielectric layer 120 and into the first opening 310. The layer of PCM fills the entire first opening, as shown in FIG. 3E.

In step 235, the layer of PCM 135′ is polished such that it is entirely removed from the uppermost surface of the upper dielectric layer 120. The uppermost surface is also polished somewhat by this process. This polishing process may, for example, comprise chemical-mechanical polishing (CMP). After polishing, the contact via 125 is formed, as shown in FIG. 3F.

Subsequently, in step 240 of the method 200, a layer of capping material 130′ for the capping layer 130 is deposited on the uppermost surface of the upper dielectric layer 120 and onto the contact via 125, as shown in FIG. 3G. In step 245, this layer of capping material is patterned to define the capping layer, as shown in FIG. 3H.

In step 250, two second openings 320 are patterned into the upper dielectric layer 120. The second openings also land on the heater 115, as shown in FIG. 3I. Once the second openings are defined, the first and second conductive elements 135, 140 may be formed concurrently using a masked deposition process comprising steps 255-275. In step 255, a seed layer 330 is conformally deposited on the uppermost surface of the upper dielectric layer, onto the capping layer 130, and into the second openings. The deposition into the second openings coats the sidewalls of the second openings and the exposed portions of the heater at the bottoms of the second openings with seed layer material. A portion of the seed layer will ultimately become part of the first and second conductive elements. Therefore, it preferably primarily comprises whatever conductive material is intended for these conductive elements (e.g., copper, aluminum, or tungsten). Nevertheless, the seed layer may also include a thin adhesion sublayer (e.g., Ti/TiN or Ta/TaN) described earlier. Such an adhesion sublayer would be deposited at the beginning of the seed layer deposition process.

In step 260, a masking layer 340 is deposited on the seed layer and patterned. This patterned masking layer will help to define where the first and second conductive elements 135, 140 are ultimately formed. The masking layer may comprise, for example, a conventional photoresist. Such a photoresist may be patterned using conventional photolithography. As indicated in FIG. 3K, the masking layer is patterned so that openings are formed over those regions of the seed layer where the first and second conductive elements are desired. In other words, the masking layer exposes a portion of the seed layer overlying the capping layer and portions of the seed layer overlying the second openings 320.

In step 265, additional conductive material is deposited onto the film stack. This deposition process is selective to the seed layer 330, meaning that the additional conductive material only deposits on the exposed seed layer and does not deposit on the patterned masking layer 340. The result of the selective deposition is the formation of the first and second conductive elements 135, 140, as shown in FIG. 3L. Nevertheless, as indicated in the figure, the conductive elements remain laterally interconnected by portions of the seed layer that underlie the masking layer.

The deposition of metallic materials on a metallic seed layer selective to masking materials like photoresist is well known in the art. Such a selective deposition process may be performed by, for example, depositing the additional conductive material using a plating process such as electroplating or electroless plating.

In step 270, the masking layer 340 is removed by, for example, a suitable chemical stripping process, as shown in FIG. 3M. Step 275 comprises etching the first and second conductive elements 135, 140 as well as the seed layer 330 to the extent necessary to remove the portions of the seed layer that are not covered with the additional conductive material. This etching process may comprise, for example, reactive ion etching (RIE) which can be configured to be highly directional. Of course, the first and second conductive elements are also thinned by such a process. Nevertheless, they are thick enough initially to survive the removal of the exposed portions of the seed layer. After completing these processing steps, the PVD 100 is formed as shown in FIG. 1.

Advantageously, the method 200 is compatible with conventional CMOS processing. That is, it does not require processing steps that are not conventionally used in modern CMOS technologies. What is more, methods in accordance with aspects of the invention may have several advantages when compared to other processing techniques for PCM-based PVDs. Other techniques for forming PCM-PVDs with structures similar to that shown herein, for example, have been observed to form high contact resistance interfaces between the heater and the conductive elements contacting the heater and between the capping layer and the conductive element contacting the capping layer. If these contact resistance are too high, the magnitude of the switching current pulse required to program the PVD may also be too high for use in conventional integrated circuits. Moreover, once programmed, the overall resistance of the PVD in its conductive state may also be too high for practical use. In contrast to these other methods for forming PCM-based PVDs, methods in accordance with aspects of the invention have shown substantially smaller contact resistances at these critical interfaces.

Methods in accordance with aspects of the invention may be utilized to form an integrated circuit. The integrated circuit design is created in a graphical computer programming language, and is stored in a computer storage medium (such as a disk, tape, physical hard drive, or virtual hard drive such as in a storage access network). If the designer does not fabricate integrated circuits or photolithographic masks used to fabricate integrated circuits, the designer transmits the resulting design by physical means (e.g., by providing a copy of the storage medium storing the design) or electronically (e.g., through the Internet) to such entities, directly or indirectly. The stored design is then converted into the appropriate format (e.g., GDSII) for the fabrication of photolithographic masks, which typically include multiple copies of the integrated circuit design in question that are formed on a wafer. The photolithographic masks are utilized to define areas of the wafer (and/or the layers thereon) to be etched or otherwise processed.

The resulting integrated circuits may be distributed by the fabricator in raw wafer form (i.e., as a single wafer that has multiple unpackaged integrated circuits), as a bare die, or in packaged form. In the latter case, the integrated circuit is mounted in a single integrated circuit package (e.g., plastic carrier with leads that are affixed to a motherboard or other higher level carrier) or in a multi-integrated circuit package (e.g., ceramic carrier that has either or both surface interconnections or buried interconnections). In any case, the integrated circuit is then integrated with other chips, discrete circuit elements, and/or other signal processing devices as part of either an intermediate product (e.g., motherboard) or an end product. The end product may be any product that includes integrated circuits, ranging from toys and other low-end applications to advanced computer products having a display, a keyboard or other input device, and a central processor.

Although illustrative embodiments of the present invention have been described herein with reference to the accompanying figures, it is to be understood that the invention is not limited to those precise embodiments, and that various other changes and modifications may be made to these embodiments by one skilled in the art without departing from the scope of the appended claims.

What is claimed is:

1. A method of forming a device, the method comprising the steps of:
providing a contact via in a dielectric layer;
providing a capping layer overlying at least a portion of the contact via; and
forming a conductive element in physical contact with the capping layer;
wherein the conductive element is formed using a masked deposition process comprising the steps of:
forming a seed layer overlying the capping layer and at least a portion of an uppermost surface of the dielectric layer;
forming a masking layer on the seed layer, the masking layer defining an opening exposing a portion of the seed layer that overlies the capping layer; and
selectively depositing a conductive material onto the exposed portion of the seed layer.

2. The method of claim 1, further comprising the step of forming a second conductive element that partially extends through the dielectric layer, the second conductive element formed at least in part using the masked deposition process.

3. The method of claim 1, wherein the step of forming the seed layer comprises forming a first sublayer comprising at least one of titanium and tantalum, and forming second sublayer comprising at least one of copper, aluminum, and tungsten.

4. The method of claim 1, wherein the seed layer and the conductive material comprise at least one material in common.

5. The method of claim 1, wherein the step of forming the masking layer comprises depositing a photoresist.

6. The method of claim 1, wherein the step of forming the masking layer comprises photolithography.

7. The method of claim 1, wherein the step of selectively depositing the conductive material comprises depositing at least one of copper, aluminum, and tungsten.

8. The method of claim 1, wherein the step of selectively depositing the conductive material comprises plating.

9. The method of claim 1, wherein the step of selectively depositing the conductive material comprises at least one of electroplating and electroless plating.

10. The method of claim 1, further comprising the steps of:
removing the masking layer; and
removing any portion of the seed layer not covered by the conductive material.

11. The method of claim 10, wherein the step of removing the masking layer comprises chemically stripping a photoresist.

12. The method of claim 10, wherein the step of removing any portion of the seed layer not covered by the conductive material comprises anisotropic etching.

13. A method of forming a device, the method comprising the steps of:
forming a contact via in a dielectric layer;
forming a capping layer overlying at least a portion of the contact via; and
forming a conductive element in physical contact with the capping layer;
wherein the conductive element is formed using a masked deposition process comprising the steps of:
forming a seed layer overlying the capping layer and at least a portion of an uppermost surface of the dielectric layer;
forming a masking layer on the seed layer, the masking layer defining an opening exposing a portion of the seed layer that overlies the capping layer; and
selectively depositing a conductive material onto the exposed portion of the seed layer.

14. The method of claim 13, wherein the step of forming the contact via comprises depositing a phase-change material, the phase-change material operative to change between lower and higher electrical resistance states in response to an application of an electrical signal to the device.

15. The method of claim 14, wherein the phase-change material comprises at least one of germanium, antimony, and tellurium.

16. The method of claim 13, further comprising the step of forming a heater proximate to the contact via, the heater operative to heat the contact via in response to an application of an electrical signal to the heater.

17. The method of claim 16, wherein the heater comprises at least one of tantalum, chromium, and ruthenium.

18. The method of claim 13, wherein the step of forming the capping layer comprises forming a diffusion barrier between the contact via and the conductive element.

19. The method of claim 18, wherein the capping layer comprises at least one of titanium and tantalum.

20. A method of forming an integrated circuit, the method comprising the steps of:
providing a contact via in a dielectric layer;
providing a capping layer overlying at least a portion of the contact via; and
forming a conductive element in physical contact with the capping layer;
wherein the conductive element is formed using a masked deposition process comprising the steps of:
forming a seed layer overlying the capping layer and at least a portion of an uppermost surface of the dielectric layer;
forming a masking layer on the seed layer, the masking layer defining an opening exposing a portion of the seed layer that overlies the capping layer; and
selectively depositing a conductive material onto the exposed portion of the seed layer.
